(19) United States
(12) Patent Application Publication
(10) Pub. No.: US 2009/0146668 A1
(43) Pub. Date: Jun. 11, 2009

(54) ANTI-PINCH SENSOR AND EVALUATION CIRCUIT

(76) Inventor: Holger WUERSTLEIN, Zeil am Main (DE)

Correspondence Address: Muncy, Geissler, Olds & Lowe, PLLC, P.O. BOX 1364, FAIRFAX, VA, 22038-1364, US

(21) Appl. No.: 12/352,894

(22) Filed: Jan. 13, 2009

Related U.S. Application Data
(63) Continuation of application No. PCT/EP2007/004909, filed on Jun. 2, 2007.

(30) Foreign Application Priority Data
Jul. 13, 2006 (DE) 20 2006 010 813.0

(51) Int. Cl. G01R 27/26

(52) U.S. Cl. 324/663

(57) ABSTRACT

An anti-pinch sensor is provided for detecting an obstacle in the path of a regulating element of a motor vehicle, the sensor can include a sensor body, a first measuring electrode that can be arranged in the sensor body and can be used to produce a first outer electrical field in relation to a counter-electrode, and an electrically separated second measuring electrode that can be arranged adjacent to the first measuring electrode in the sensor body and can be used to produce a second outer electrical field in relation to the counter electrode. The measuring electrodes can be formed in such a way that the first outer electrical field has a larger range than the second outer electrical field. An evaluation circuit is also provided that is suitable for evaluating an anti-pinch sensor. The detection reliability of such a clamping sensor is not affected by dirt or water on a surface thereof.

This nonprovisional application is a continuation of International Application No. PCT/EP2007/004909, which was filed on Jun. 2, 2007, and which claims priority to German Patent Application No. 20 2006 010 813.0, which was filed in Germany on Jul. 13, 2006, and which are both herein incorporated by reference.

### BACKGROUND OF THE INVENTION

1. Field of the Invention

The invention relates to an anti-pinch sensor, particularly for detecting an obstacle in the path of an actuating element of a motor vehicle. Further, the invention relates to an evaluation circuit for an anti-pinch sensor of this type.

2. Description of the Background Art

Conventional anti-pinch sensors utilize, for example, a capacitive measuring principle to detect an obstacle. In this case, an electric field is created between a measuring electrode and a suitable counter electrode. If a dielectric enters this electric field, the capacitance of the capacitor formed by the measuring electrode and the counter electrode changes. Theoretically, an obstacle in the path of an actuating element of a motor vehicle can be detected in this way, provided its relative dielectric constant ∈ᵣ differs from the relative dielectric constant of air. The obstacle in the path of an actuating element is detected without physical contact with the anti-pinch sensor. If a change in capacitance is detected, countermeasures, such as, for example, stopping or reversing of the drive, can be initiated in a timely fashion, before an actual pinching of the obstacle occurs.

In the case of actuating elements of a motor vehicle, this may refer, for example, to an electrically actuated window, an electrically actuated sliding door, or an electrically actuated hatch door. An anti-pinch sensor, based on the capacitive measuring principle, may be used for detecting an obstacle in the case of an electrically actuated seat.

Non-contact anti-pinch sensors, based on the capacitive measuring principle, are known, for example, from European Pat. Applications Nos. EP 1 455 044 A2, which corresponds to U.S. Pat. No. 7,046,129, and EP 1 154 110 A2, which corresponds to U.S. Pat. No. 6,337,549. These anti-pinch sensors generate an external electric field by a measuring electrode and a suitable counter electrode, so that a dielectric entering this external electric field may be detected as a change in the capacitance between the measuring electrode and counter electrode. To be able to assure a high reliability in the detection of pinching, in addition the distance between the measuring electrode and counter electrode in the two prior-art anti-pinch sensors is designed as flexible, as a result of which physical contact between an obstacle and the anti-pinch sensor can also be detected as a change in capacitance.

European Pat. Application No. EP 1 371803 A1, which corresponds to U.S. Pat. No. 6,936,986, discloses an anti-pinch sensor based on the capacitive measuring principle. In this case, a sensor electrode, which is connected via a screened feed line to an evaluation unit, is used to generate an electric field within the opening range of the actuating element. The electric field is generated in this case relative to the body of a motor vehicle as the counter electrode.

A disadvantage of the conventional anti-pinch sensors, based on the capacitive measuring principle, is the risk of a misdetection of pinching, when there is dirt or water on the sensor. Dirt or water also leads to an altered capacitance, so that a conclusion on a case of pinching would be erroneously reached.

### SUMMARY OF THE INVENTION

It is therefore an object of the invention to provide an anti-pinch sensor operating according to the capacitive measuring principle, with which the risk of misdetection in the case of deposition of dirt or water is as low as possible. Further, it is an object of the invention to provide a suitable evaluation circuit, with which the risk of misdetection in the case of a dirty or water-exposed sensor is as low as possible.

In an embodiment, a sensor body is provided that comprises a first measuring electrode for generating a first external electric field relative to a counter electrode and an adjacent, electrically separated second measuring electrode for generating a second external electric field relative to the counter electrode, whereby the measuring electrodes are formed in such a way that the first external electric field has a broader range than the second external electric field.

In contrast to conventional anti-pinch sensors, based on the capacitive measuring principle, accordingly two electrically separated measuring electrodes are present, each of which generates an electric field relative to a counter electrode. The counter electrode in this case can be part of the anti-pinch sensor itself. The counter electrode can also be formed, however, by the grounded body of a motor vehicle.

It is known that dirt or water causes a misdetection of the anti-pinch sensor because of the resulting change in capacitance, as deposits impact the surface of the sensor body. In other words, dirt or water via a near field effect leads to a change in capacitance of the capacitor formed between the measuring electrode and counter electrode.

Further, it should be appreciated that an obstacle in the path of the actuating element should be detected even before physical contact with the anti-pinch sensor from a change in capacitance. In other words, the electric field of an anti-pinch sensor, based on the capacitive measuring principle, extends into the opening range of the actuating element to be able to detect an obstacle without contact. A change in capacitance caused by an obstacle in the path of travel of the actuating element is accordingly to be detected at a distance from the direct surface of the sensor body. Therefore, a change in capacitance caused by dirt or water differs from a change in capacitance caused by the approach to an obstacle in the site of its origin.

In an embodiment, the invention recognizes that this difference can be utilized for separating a case of pinching from a dirt or wetting situation to avoid misdetection. This is achieved in an embodiment, by using at least two electrically separated measuring electrodes to create an external electric field relative to a counter electrode. A change in capacitance at the surface of the sensor body can be differentiated from a change in capacitance caused by an obstacle upon approach because one of the measuring electrodes is designed to generate an electric field with a broader range compared with the electric field of the other measuring electrode.

If dirt or water is present as a deposit or as moisture on the surface of the sensor body, this causes a change in the capacitance of both the capacitor having a first measuring electrode and counter electrode and the capacitor, which can include the second measuring electrode and counter electrode. An obstacle approaching from the far field, in contrast, causes primarily a change in the capacitance of the capacitor that forms an electric field projecting further into the opening area. Whereas the near field is still not affected by the dielectric properties of the obstacle and therefore no change in capacitance is detected, the obstacle is already detected via the electric field with a broader range of the other measuring electrode or detectable as a change in capacitance.

The described anti-pinch sensor accordingly allows the detection and in this respect the differentiation of a dirt deposit or wetting by water on the surface of the sensor body as a direct current signal and an approaching obstacle as a differential signal.

The different range of the electric fields generated by the measuring electrodes can thereby be influenced or achieved by the geometry and/or dimensioning of capacitor arrangements in each case comprising a measuring electrode and the counter electrode. Thus, for example, the second measuring electrode to achieve as short-range an electric field as possible can be designed in such a way that the field lines have as direct a course as possible between the measuring electrode and counter electrode. On the other hand, the second measuring electrode can be designed, arranged, or dimensioned in such a way that the field lines of the generated electric field, like a stray-field capacitor, take as long a detour as possible through the opening area of the actuating element. The second measuring electrode can also be arranged in the immediate vicinity of the counter electrode, whereas the first measuring electrode is located at a distance from the counter electrode. A direct electric field forming between a measuring electrode and counter electrode, as well as a stray field, can be used basically for the detection. A combination of both options is also conceivable.

In an embodiment, the first measuring electrode, i.e., the measuring electrode for generating the electric field with the broader range, is located at a distance from the edge in the sensor body and the second measuring electrode is arranged in an edge region. This embodiment is an option particularly for an anti-pinch sensor whose sensor body is placed on a counter electrode, such as a grounded body of a motor vehicle. If the measuring electrodes are at a different potential from the counter electrode, then, a direct stronger electric field will form in the space between the measuring electrodes and the counter electrode (i.e., in the insulating body), and a weak electric external or stray field in the space facing away from the counter electrode and in the edge regions around the measuring electrode. The external field is used for the non-contact detection of a dielectric.

Because the second measuring electrode is arranged at the edge of the sensor body, the external electric field is concentrated predominantly in the spatial area between the edge of the measuring electrode and the counter electrode. The external electric field of the second measuring electrode is therefore overall short-ranged. Moreover, it barely extends into the open space facing away from the counter electrode. However, an external electric field whose field lines proceed along curved paths between the first measuring electrode and the outer counter electrode and therefore extend into the space facing away from the counter electrode, i.e., into the opening area of an actuating element, forms between the first measuring electrode, which is arranged at a distance from the edge of the sensor body, and the counter electrode.

In an embodiment of the invention, the measuring electrodes can each be formed such that they are substantially or completely flat. In this case, the capacitance of the capacitor forming with the counter electrode can be determined or adjusted in a known manner via the size of the area. Thus, it is possible to adjust the ratio of the capacitances formed by the first or second measuring electrode via the area ratio of the measuring electrodes to one another.

The range of the electric field extending into the opening area can also be increased by increasing the area of the first measuring electrode. In this respect, it is advantageous if the area of the first measuring electrode is greater than the area of the second measuring electrode. A capacitance adjustment, desired for evaluating the change in capacitance, of the capacitors comprising the first and second measuring electrode can be achieved by a combination of arrangement and dimensioning; here, in particular the later use of the anti-pinch sensor and thereby the geometry of a vehicle body are also to be considered.

The measuring electrodes can be dimensioned in such a way that a dielectric brought into the immediate vicinity in both external electric fields essentially causes no drift in the measurement capacitances relative to one another. In other words, the dimensioning is selected in such a way that dirt deposits or water on the surface of the sensor body results in an approximately identical change in capacitances of the capacitor comprising the first and/or second measuring electrode. A differential signal formed from the capacitances of the two capacitors consequently essentially undergoes no or only a negligible change due to the soiling or wetting with water of the sensor body.

This type of design permits a relatively simple separation of a case of pinching in terms of circuitry (whereby a dielectric in the far field results in a divergence of the capacitances of the two capacitors) from soiling in the near field, whereby a capacitance differential signal does not change. In terms of circuitry, for this purpose, only a zero signal must be separated from a signal not equal to zero.

In an alternative embodiment, the measuring electrodes are dimensioned in such a way that a dielectric brought into the immediate vicinity in both external electric fields can cause a drift in the measurement capacitances to one another with a different sign than a dielectric in the far field, which is identifiable with a case of pinching. An approaching obstacle is first penetrated by the field lines of the external electric field with a greater range, as a result of which the capacitance of the capacitor comprising the first measuring electrode increases. The obstacle initially has no effect on the capacitance of the capacitor comprising the second measuring electrode. Soiling or wetting with water in the near field, in contrast, has an effect on both measurement capacitances. The capacitance formed by the second measuring electrode is more greatly affected, however, because the second measuring electrode with appropriate dimensioning generates an electric field with a smaller range and spread. Therefore, soiling or wetting in the near field results in a drift in the measurement capacitances with a different sign than an obstacle approaching from the far field. The signal of a change in capacitance, caused by soiling or wetting with water of the sensor body, can again be separated in a relatively simple manner in terms of circuitry from the signal of a change in capacitance, which is caused by a dielectric in the far field.

The dimensioning of the measuring electrode can be determined experimentally or by computer simulation. Care should be taken in that the dimension of the first measuring electrode relative to the second measuring electrode depends greatly on the geometry and the material of the sensor body. To maintain the smallest possible drift in measurement capacitances to one another in the case of a deposit or moisture on the sensor body, it is desirable that the first measuring electrode is relatively large in relation to the second measuring electrode to achieve a broad useful field expansion. The actual dimensions can be determined by simulation with consideration of the actual materials and geometries to be used. Because, as already stated, deposition of material or a water film has a greater effect on the second measuring electrode, which generates a shorter-ranged electric field, than on the first measuring electrode or on the specifically associated capacitances, the area of the first measuring electrode is to be dimensioned appropriately smaller.

To avoid edge effects on the electric field, formed by the first measuring electrode, it is advantageous to arrange in an edge region of the sensor body a separate third measuring electrode which is adjacent to the first measuring electrode and is connected parallel to the second measuring electrode. In other words, the first measuring electrode for generating the external electric field with a broader range can be located between the second and third measuring electrodes, each of which is arranged in the edge area of the sensor body to generate an external electric field with a short range. In this way, particularly in a design of the anti-pinch sensor as a flat cable, a symmetric design is achieved to the effect that the measuring electrodes to generate the short-ranged external electric field are arranged at the long sides in each case, as a result of which the electric field generated by the first centrally arranged measuring electrode by necessity extends over a large useful field area. Edge fields between the edge of the first measuring electrode and the counter electrode, on which the anti-pinch sensor is placed, are hereby avoided.

For an anti-pinch sensor constructed in this way, it is advantageous to design the sensor body as flat and to arrange the measuring electrodes in the sensor body in each case as parallel flat conductors. For a sensor body with a width of about 10 mm, it has been determined that no drift in the measurement capacitances relative to each other occurs due to wetting with water or surface soiling, when the centrally arranged first measuring electrode has a width of about 4.8 mm and the other measuring electrodes each have a width of about 1.8 mm. In this case, the performed simulation provides the lowest capacitance drift when the measuring electrodes are separated from one another in each case by the sensor body by a distance of about 0.7 mm and the sensor body has an edge region with a thickness of about 0.1 mm relative to the outer measuring electrodes.

To achieve a useful electric field with a broad range, the sensor body can provide for a separate shielding electrode, which is arranged in a hazard region or in the space facing away from the counter electrode, relative to the measuring electrodes to align at least the first external electric field. If, for example, the body of a motor vehicle is used as the counter electrode, on which the anti-pinch sensor is placed, then the separate shielding electrode is to be arranged between the vehicle body and the measuring electrodes in the sensor body. A potential equalization between the potential of the measuring electrodes and the potential of the shielding electrode has the result that no direct electric fields and therefore no direct capacitance form between the measuring electrode and the counter electrode. Rather, the field lines of the electric field between the measuring electrode and the counter electrode are directed into the hazard region to be detected. It is ensured by the dimensioning or arrangement of the second or third measuring electrode that the external electric field generated by this measuring electrode has a smaller range than the external electric field generated by the first measuring electrode. This is achieved, for example, with the already mentioned arrangement of the second or third measuring electrode in an edge region of the sensor body.

In an embodiment, the shielding electrode can be designed as a coherent flat conductor. In another embodiment, however, the shielding electrode can be divided into individual, separate single shielding electrodes, each arranged opposite the measuring electrode. This permits a better potential equalization relative to the individual measuring electrodes to be shielded. The described shielding electrodes, whose potential is adjusted to the measuring electrodes, are also called driven-shield electrodes.

In a further embodiment, the sensor body can be made of a flexible support material. This permits running the anti-pinch sensor easily along the contour of a closing edge of a motor vehicle. In particular, the sensor body can be formed as a flexible flat cable. It is just as readily conceivable to design the sensor body as a sealing body or to integrate the sensor body into a sealing body. The sealing body is provided thereby to seal the actuating element relative to the closing edge in the closed state. A sealing lip can be mentioned as an example of this, which seals an actuatable side window of a motor vehicle relative to its closing edge.

A flexible flat cable is also called an FFC and is notable in that parallel conductor structures are placed in the flexible cable body.

As an alternative to an FFC, a flexible conductor structure may also be used as the sensor body. A flexible conductor structure is also known under the term FPC (Flexible Printed Circuit). In this case, traces are specifically arranged or laid out in a flexible insulating material, particularly in a multilayer arrangement. This type of design permits a high flexibility with respect to the dimensioning and arrangement of the individual traces, so that the measuring electrode of the anti-pinch sensor can be arranged or dimensioned in a desired manner.

In another embodiment, the sensor body can extend in a longitudinal direction, whereby the measuring electrodes are split along the longitudinal direction each into individually controllable single electrodes. It is achieved thereby that the capacitance measurable between the measuring electrode and the counter electrode declines, because the entire area of the measuring electrode is divided into several interrupted individual areas of the separated electrodes. A low capacitance, forming overall between the measuring and counter electrode, however, has the result that a small change in capacitance relative to the total capacitance can be detected more easily. The ratio of the change in capacitance and total capacitance shifts in favor of the change in capacitance. An anti-pinch sensor designed in this way, moreover, allows the detection of a change in capacitance by means of a multiplex process. In this case, the individual electrodes can be controlled by means of separate feed lines either displaced in time (serially) or simultaneously (parallel).

An option hereby is to arrange the feed lines to the single electrodes in the sensor body in each case between the shielding electrode sections. As a result, direct capacitances between the lines are also reliably avoided.

Further, an evaluation circuit is provided that comprises measuring potential output means to output a predefined measuring potential to the measuring electrodes, capacitance drift detection means to detect a mutual drift of measurement capacitances between measuring electrodes and a counter electrode, and evaluation means to output a detection signal as a function of the drift signal.

The measuring potential output means are used to generate a measuring potential which is necessary for detecting the measurement capacitances and which is applied at the measuring electrodes.

For this purpose, the measuring potential output means may comprise, for example, a direct voltage generator or alternating voltage generator. Thus, a measurement capacitance can be detected, for example, by a charging time evaluation via a direct voltage generator. An alternating voltage generator enables detection of the measurement capacitances via its complex resistance or AC resistance by means of a voltage divider. A controllable alternating voltage generator also enables the detection of the measurement capacitances via phase mismatching. The measuring potential output means can also be designed to be able to detect the measurement capacitances via oscillating or resonant circuit detuning.

The capacitance drift detection means can be realized by electronic components. In particular, however, signals can be digitized and compared to one another by means of a computer, subjected to a logic operation, or processed in some other way, to be able to determine as a drift signal a change in the distance or the difference in the measurement capacitances.

The evaluation means can be designed to conclude from the detected drift signal that there is a case of pinching and in such a case to generate a corresponding detection signal. The evaluation means may also be realized by means of electronic components or by suitable software and an appropriate computer.

In an embodiment, the evaluation means are designed to output a detection signal when there is a time change in the drift signal within an area corresponding to the closing time of the actuating element. An evaluation circuit designed in such a way offers the advantage of reliably differentiating a drift in the measurement capacitances, caused by an obstacle in the far field upon approach to the anti-pinch sensor, from a drift, caused, for example, by changes in temperature or material stresses. The time change in the drift signal caused by a case of pinching moves within a time frame corresponding to the closing speed of the actuating element. In this respect, this type of design makes possible an increase in detection reliability, because misdetections are reduced.

Further, potential equalization means can be included for potential equalization between the shielding electrode and measuring electrode of the anti-pinch sensor. In particular, the potential equalization means may be formed by an amplifier, which can be connected on the input side to the measuring electrodes and on the output side to a shielding electrode to supply them with a voltage signal derived from the input signal. It is possible with this type of circuit to use the shielding electrode as a driven shield to prevent the formation of direct capacitances between the measuring electrode and the counter electrode.

In a first alternative, the measuring potential output means can comprise an alternating voltage source, whereby additional differential signal generation means are provided for forming a differential signal corresponding to the difference of the measurement capacitances, and whereby the drift signal detection means are designed to detect the drift of the differential signal, i.e., to detect a change in the differential signal.

An alternating voltage of the desired value and frequency can be applied by the measuring potential output means between the measuring electrode and counter electrode. The difference in the measurement capacitances can then be formed, for example, by detection of the corresponding alternating voltage resistances, so that detection of a change or drift in the differential signal becomes possible.

A case of pinching can be concluded reliably from the drift of the differential signal. Misdetection due to soiling or wetting is avoided depending on the design of the anti-pinch sensor, because the drift in the differential signal caused by this differs, for example, in value or sign from the drift caused by an obstacle approaching from the far field.

In an embodiment, the differential signal generation means for detecting the measurement capacitances each comprise a bridge circuit, the measurement capacitances in the bridge branches being connected in parallel. Thus, a differential signal, which corresponds to the difference in measurement capacitances, can be determined in a manner relatively simpler in terms of circuitry by tapping of the voltages declining at the measurement capacitances or by a phase difference in voltages in the two bridge branches. In the first case, a differential amplifier is an option which forms the difference of the voltages declining at the capacitances. For this purpose, peak value detection, for example, can be connected upstream of the differential amplifier.

In the second case, the phase difference in the voltages tapped in the bridge branches can be determined by a phase difference detection means. The phase difference detection means can be formed, for example, by comparators, which form a square-wave signal from the tapped alternating voltage, and an XOR logic module. This design is an option when the anti-pinch sensor is dimensioned in such a way that soiling or wetting of the sensor body does not result in a drift in the measurement capacitances relative to each other, so that in this case the output signal of the XOR logic module remains at zero.

In a further alternative embodiment of the evaluation circuit, the measuring potential output means comprise in each case an alternating voltage generator, whereby additional phase difference detection means are provided to detect a phase difference between the measurement capacitance branches, and whereby the drift signal detection means are formed to detect the phase position.

In this case, the measurement capacitance branches are each provided with an accurately predefined alternating voltage with the same frequency. The phase mismatching can be compensated by a suitable change in the phase position of the two alternating voltage generators relative to each other via a suitable control loop. The drift in the phase position is thus detectable via a necessary readjustment of the alternating voltage signals.

The measurement capacitances can be assigned at least one controllable balancing capacitance, whereby the evaluation means for equalizing the measurement capacitances are formed by controlling the at least one balancing capacitance. This type of balancing capacitance enables an equalizing of the measurement capacitances in a long-time drift, which is caused, for example, by a change in geometry or a change in material. A controllable balancing capacitance can also be used to achieve that the measurement capacitances of the first and second (and optionally third) measuring electrode can be set to the same value without a case of pinching. As a result, it is possible, on the one hand, to compensate for surface soiling or wetting of the anti-pinch sensor by means known in circuit engineering and, on the other, to reliably detect a case of pinching.

Voltage-controlled capacitance diodes, operated in the blocking direction and separated in each case from the measurement capacitances by a coupling capacitor, can be used as controllable balancing capacitances. In this case, it is expedient if the evaluation means are designed to control the balancing capacitances as a function of the drift signal. It is therefore possible to compensate for a long-time drift.

The stated object can also be achieved according to the invention by means of a module that comprises the described anti-pinch sensor and the described evaluation circuit.

The described anti-pinch sensor and the described module, comprising this type of anti-pinch sensor, are particularly suitable for use in a motor vehicle, the grounded body of the motor vehicle being used as the counter electrode.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows, in a cross section, an anti-pinch sensor arranged on a counter electrode;

FIG. 2 shows schematically the anti-pinch sensor of FIG. 1 with a simplified depiction of field lines of the external electrical field generated to the counter electrode;

FIG. 3 shows in a diagram the resulting capacitances in the case of a wetted anti-pinch sensor of FIG. 1;

FIG. 4 shows in a cross section schematically another anti-pinch sensor with a shielding electrode and the course of the field lines;

FIG. 5 shows in a cross section schematically an alternative anti-pinch sensor with a shielding electrode, segmented measuring electrodes, and the course of the field lines;

FIG. 6 shows a measuring bridge circuit to detect the measurement capacitances;

FIG. 7 shows schematically a circuit arrangement for the formation of a differential signal corresponding to the difference in the measurement capacitances; and

FIG. 8 shows schematically another circuit arrangement for the formation of a differential signal corresponding to the difference in the measurement capacitances.

### DETAILED DESCRIPTION

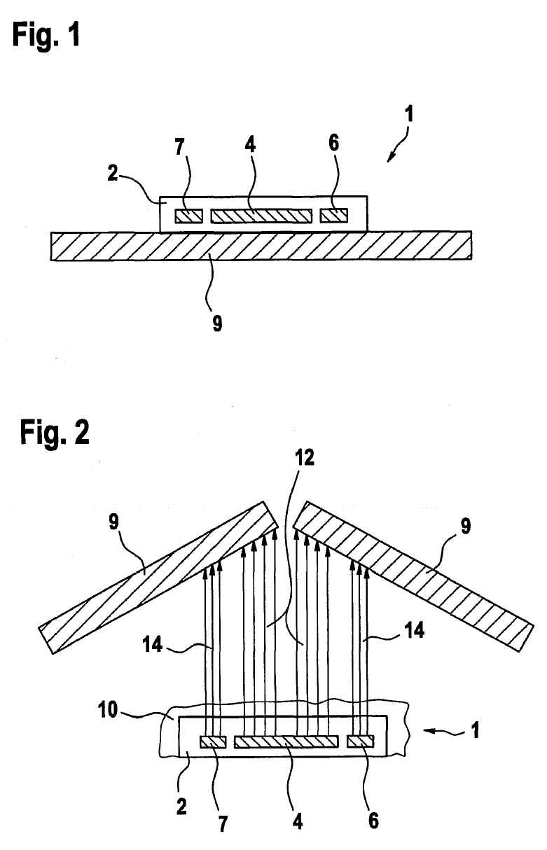

FIG. 1 shows schematically the cross section of an anti-pinch sensor 1, which can be used in particular for detecting an obstacle in the path of an actuating element of a motor vehicle. The anti-pinch sensor 1 can include an elongated sensor body 2 made of an electrically insulating material. In the sensor body 2, approximately in the center, a first measuring electrode 4 is placed between a second measuring electrode 6 and a third measuring electrode 7. Measuring electrodes 4, 6, and 7 are each formed as flat conductors. Anti-pinch sensor 1 is placed on a counter electrode 9, which, for example, can be formed by the grounded body of a motor vehicle.

To use anti-pinch sensor 1, measuring electrodes 4, 6, and 7, for example, are supplied with an alternating voltage relative to counter electrode 9. In this case, measuring electrodes 6 and 7 are connected electrically parallel to one another. Based on the potential difference, a direct electric field forms in insulating body 2 between measuring electrodes 4, 6, and 7 and counter electrode 9 and a weaker external electric field in the space facing away from counter electrode 9. Measuring electrodes 4, 6, and 7 each form a capacitor with counter electrode 9 with a characteristic capacitance determined by the dimensioning of anti-pinch sensor 1 and by the material of sensor body 2. In this case, measuring electrodes 6 and 7 act as a single capacitor due to their parallel connection.

Only a weak external electric field with a small range forms by the arrangement of the second and third measuring electrode 6 or 7 at the edge of sensor body 2. Due to the shielding effect of outer measuring electrodes 6 and 7, however, the field lines of the external electric field, which is generated by the inner first measuring electrode, are deflected into a larger spatial region facing away from the counter electrode. The field lines of the external electric field of the capacitor formed by counter electrode 9 and inner measuring electrode 4 proceed along a curved path to both sides over outer electrode 6 or 7 to counter electrode 9. Thus, a dielectric approaching anti-pinch sensor 1 from the far field is first penetrated by the field lines of the capacitor comprising first measuring electrode 4 and in this capacitor results in a corresponding change in capacitance. The capacitance of the capacitor comprising second and third measuring electrode 6 or 7 is not influenced by a dielectric located in the far field.

The capacitances of both capacitors is influenced in the near range and particularly in the case of dirt located flat on sensor body 2 or wetting with water on the surface. Thus, anti-pinch sensor 1 permits a case of soiling by superficial dirt or by a superficial water film to be reliably differentiated from a case of pinching, which is characterized by the approach of an obstacle from the far field.

In FIG. 2, the field configuration of anti-pinch sensor 1 of FIG. 1 is shown in a simplified diagram. In this case, for better understanding, counter electrode 9 is divided theoretically in the center below anti-pinch sensor 1 of FIG. 1 and the resulting halves are folded upward.

A straight course of the field lines of the arising external electric fields results from this simplified depiction.

For illustration, further, a film of water 10 is depicted on the surface of sensor body 2 of anti-pinch sensor 1 as soiling.

The course of the field lines of the first external electric field 12 is evident, which forms at a potential difference between the centrally arranged measuring electrode 4 and counter electrode 9. Further, the course of the field lines of a second external electric field 14 is visible, which forms accordingly at a potential difference in each case between measuring electrodes 6 and 7, arranged at the edge, and counter electrode 9.

In this schematic depiction, the direct capacitance, definitive for the shown anti-pinch sensor 1, between measuring electrodes 4, 6, and 7 and counter electrode 9 are eliminated theoretically and graphically. The depicted course of the field lines corresponds to those of the external, rather weak stray fields. It is evident that external electric field 12, used for the non-contact detection of a dielectric, of measuring electrode 4 has a broader range than external electric field 14, generated by measuring electrodes 6 and 7 arranged at the edge.

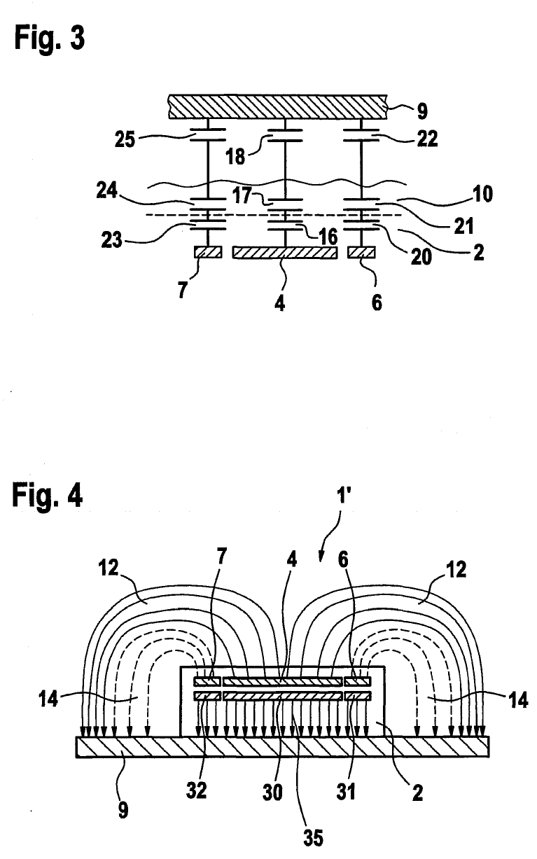

The structure of the measurement capacitances of the capacitors formed by respective measuring electrodes 4, 6, and 7 and counter electrode 9 is vividly clear from the depiction according to FIG. 2. This is shown in a diagram in FIG. 3.

Measuring electrodes 4, 6, and 7 and the “folded” counter electrode 9 are again evident. A water film 10 is again present on measuring electrodes 4, 6, and 7 or on sensor body 2 in the form of surface wetting.

It is understandable that the measurement capacitances of each measuring electrode 4, 6, or 7 are made up of three single capacitances connected in series in terms of circuitry. The material of sensor body 2, water film 10, and air as a transmission medium are arranged between each measuring electrode 4, 6, and 7 and counter electrode 9. In this respect, the capacitance of the capacitor comprising first measuring electrode 4 can be regarded as a series connection of capacitances 16, 17, and 18. Accordingly, the capacitances formed by outer measuring electrodes 6 and 7 can each be considered as a series connection of capacitances 20, 21, and 22 or 23, 24, and 25.

To increase the stray field of the capacitors formed by measuring electrodes 4, 6, and 7, a shielding electrode is introduced between measuring electrodes 4, 6, and 7 and counter electrode 9 by anti-pinch sensor 1′ depicted in a cross section according to FIG. 4. In this case, the shielding electrode is divided into a first, second, and third shielding electrode 30, 31, or 32, each of which is assigned to the corresponding measuring electrode 4, 6, or 7. Via a suitable circuit, not shown here, it is achieved by circuitry means that shielding electrodes 30, 31, and 32 are in each case at the same potential as measuring electrode 4, 6, or 7. In other words, shielding electrodes 30, 31, and 32 are used as so-called driven shield electrodes. Based on the resulting potential ratios, therefore shielding electrodes 30, 31, and 32 prevent the formation of a direct capacitance or a direct electric field between measuring electrodes 4, 6, and 7 and counter electrode 9. Therefore, a stray field to counter electrode 9, which extends into the detection range of anti-pinch sensor 1′, is generated in each case via measuring electrodes 4, 6, and 7. The detection range of anti-pinch sensor 1′ compared with the detection range of anti-pinch sensor 1 is considerably increased.

By the edge arrangement of measuring electrodes 6 and 7, external electric field 14, which is created by said electrodes and shown as a hatched area, has a smaller range than external electric field 12 generated by inner measuring electrode 4.

The direct electric field is moreover generated from shielding electrodes 30, 31, and 32 to counter electrode 9, which is illustrated by the appropriately drawn field lines of direct electric field 35. Therefore, in the case of anti-pinch sensor 1′, outer measuring electrodes 6 and/or 7 at the edge and the centrally arranged measuring electrode 4 again achieve that the range of the correspondingly generated external electric fields 12 and 14 differs. This makes possible compensation of soiling lying superficially on sensor body 2 or a superficial water film. It is achieved in addition via the size ratios of the second and third measuring electrode 6 or 7 to the inner first measuring electrode 4 that in the case of superficial soiling or superficial wetting with water the capacitance formed by the first measuring electrode 4 and the capacitance formed by the parallel connected second and third measuring electrodes 6 and 7 change in a similar way. It is achieved thereby that superficial soiling of sensor body 2 does not affect a differential signal of the measurement capacitances, whereas an obstacle or a dielectric approaching from the far field, which represents a case of pinching, results in a change in the differential signal.

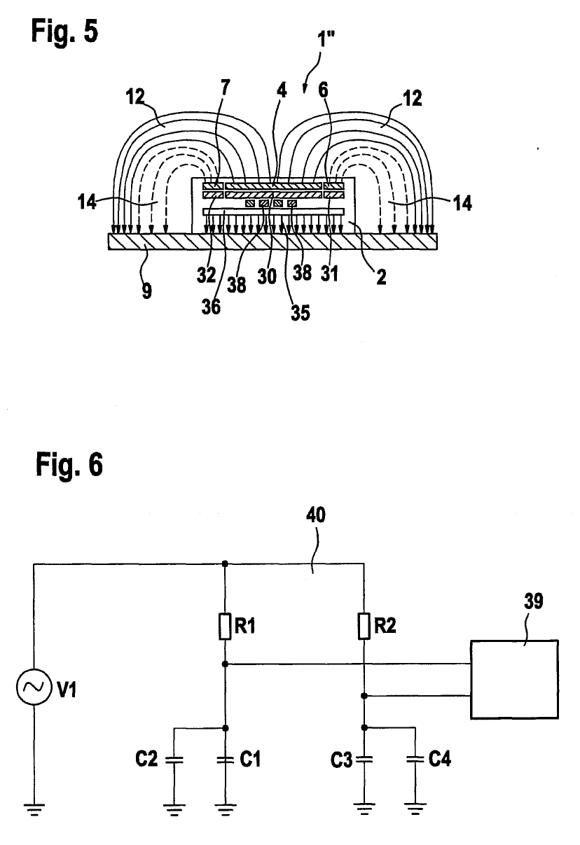

Another anti-pinch sensor 1″ is again shown in a cross section in FIG. 5. It comprises substantially the individual components of anti-pinch sensor 1′, as it is shown in FIG. 4. Anti-pinch sensor 1″ also comprises a flat sensor body 2, extending in the longitudinal direction and made of an electrical insulating material, which is placed on a counter electrode 9. Inner measuring electrode 4 and outer measuring electrodes 6 and 7 are each formed as flat conductors. Likewise, shielding electrodes 30, 31, and 32 are formed as flat conductors, which are assigned to the corresponding measuring electrodes 4, 6, or 7. The formation of a direct capacitance between measuring electrodes 4, 6, and 7 and counter electrode 9 is again prevented by shielding electrodes 30, 31, and 32. In this respect, the course of field lines of the generated external electric field 12 of inner measuring electrode 4 and of generated electric field 14 of the parallel connected outer measuring electrodes 6 and 7 is identical to the course of field lines of anti-pinch sensor 1′ of FIG. 4.

In addition, anti-pinch sensor 1″ shown in FIG. 5 comprises a fourth flat screening electrode 36, which is at the same potential as the other shielding electrodes 30, 31, and 32 or is connected to the electrodes by circuitry. In this respect, direct electric field 35 arises between the fourth shielding electrode 36 and counter electrode 9.

Measuring electrodes 4, 6, and 7 are divided (not shown) in the longitudinal direction of anti-pinch sensor 1″, i.e., into the plane of the drawing, into several single electrodes separated from one another. Additional separate feed lines 38, which in each case are contacted with one of the single electrodes, are arranged between shielding electrodes 30, 31, and 32 and the fourth shielding electrode 36. All single components are therefore isolated from one another by the electrical insulation material of sensor body 2. Shielding electrode sections, which prevent the formation of direct capacitances between the separate feed lines 36, can be arranged in each case between the separate feed lines 38. The separate feed lines 38 are used to control the single segments or single electrodes of measuring electrodes 4, 6, and 7. Each single electrode of the measuring electrodes along the longitudinal direction of anti-pinch sensor 1″ can therefore be controlled and evaluated via the separate feed lines 38. This permits multiplexing, on the one hand, and position resolution of a possible pinching case, on the other.

FIG. 6 shows a possible evaluation circuit for evaluating one of the anti-pinch sensors 1, 1′, or 1″ shown in FIGS. 1 to 5. For this purpose, the evaluation circuit of FIG. 6 comprises an alternating voltage source V1 for generating a defined alternating voltage. Further, the shown evaluation circuit comprises a measuring bridge circuit 40 to detect the measurement capacitances. In this case, the measuring bridge circuit is made of two bridge branches, each of which comprise ohmic resistance R1 or R2 and a measurement capacitance C1 or C3. Measurement capacitance C1 of the first bridge branch is formed thereby by the first measuring electrode 4 and counter electrode 9 of the shown anti-pinch sensors 1, 1′, 1″. Measurement capacitance C3 is the capacitance of the capacitor formed by the parallel connected outer shielding electrodes 6 and 7 and counter electrode 9 according to the depicted anti-pinch sensors 1, 1′, 1″. Via a respective voltage tap between the ohmic resistances R1, R2 and the assigned measurement capacitances C1 or C3, it is possible for a suitably formed evaluation means 39 to form the differential signal corresponding to the difference of measurement capacitances C1, C3 and to derive a drift signal therefrom.

The evaluation circuit according to FIG. 6 comprises further balancing capacitances C2 and C4, assigned to measurement capacitances C1, C3 and formed by the voltage-controlled capacitance diodes operated in the blocking direction. It is possible via a corresponding control of balancing capacitances C2 and C4 to balance a long-time effect, on the one hand, and to compensate an offset of the differential signal, on the other.

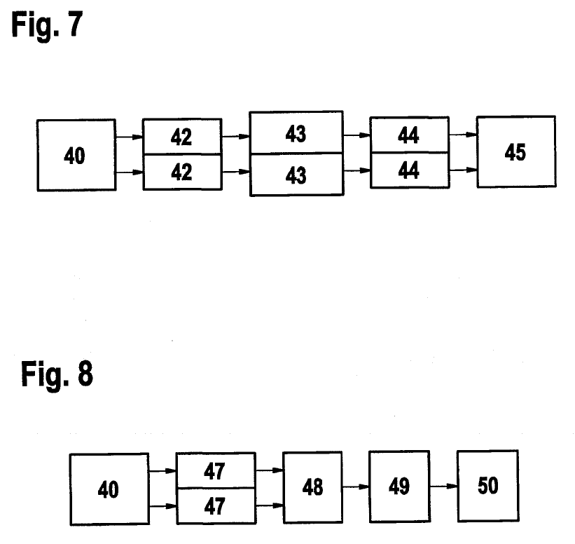

Possible embodiments of evaluation means 39, for example, an evaluator, are shown schematically in FIGS. 7 and 8. Measuring bridge circuit 40 is shown in this case as the input member in FIGS. 7 and 8.

According to FIG. 7, voltage values obtained from measuring bridge circuit 40 are first supplied to an amplifier 42. Further, a peak value detection 43, which determines the maximum amplitude of the detected alternating voltages, is connected downstream of each amplifier 42. A lowpass filter 44 is connected downstream in each case to obtain good noise suppression. Finally, the obtained maximum values are supplied to a differential amplifier 45.

If the anti-pinch sensor is dimensioned in such a way or adjusted with the balancing capacitances, so that the measurement capacitances C1+C2 and C3+C4 are the same and exhibit no drift to one another in the case of superficial soiling or wetting, the output signal of differential amplifier 45 can be used directly as a detection signal. Dirt or wetting by a superficial water film is actually capable in this case of not causing a drift between the measurement capacitances. The differential signal remains at zero. A drift in the measurement capacitances is generated, however, by a dielectric approaching from the far field. Said dielectric is first penetrated only by the field lines of external electric field 12, which is produced by the inner measuring electrode 4 of the shown anti-pinch sensors.

In an alternative embodiment according to FIG. 8, the detected voltages of measuring bridge circuit 40 are first supplied to a comparator 47. To this end, the generation of a comparison voltage is necessary with a justifiable expense. A square-wave voltage is generated by the comparator with the approximately sinus-shaped output signal. The thus generated square-wave voltages are supplied to an exclusive OR logic module (XOR) 38. Thus, no output signal of logic module 48 results when both square-wave signals are identical. On the other hand, an output signal arises when the square-wave signals differ in their phase.

The output signal of logic module 48 is then supplied to a lowpass filter 49 for noise suppression and relayed to an amplifier 50. The output signal of amplifier 50 can be used in turn as a detection signal for a pinching case. A drift in the measurement capacitances C1, C3 to one another will lead to a phase mismatching of the voltages tapped at the measurement capacitances in measuring bridge circuit 40 and thereby result in an output signal of logic module 48.

The balancing capacitances C2 and C4 shown in FIG. 6 are used to equalize measuring bridge circuit 40 in the long term, whereby relatively rapid changes by the approach of an object are not corrected.

The balancing capacitances C2 and C4 are controlled by a microcontroller as a function of the output signal from the evaluation circuit. This is typically realized by a direct voltage or a lowpass-filtered PWM signal with a variable duty cycle. This direct voltage then controls the capacitance diodes used as balancing capacitances C2 and C4 and operated in the blocking direction, which are separated from the bridge branch in terms of circuitry in each case by a capacitor (not shown in FIG. 6). The control is selected in such a way that a balanced relation is achieved from the adjustment of a long-time drift and the detection of short-time changes by an object.

The equalizing of the bridge branches of measuring bridge circuit 40 further achieves that no parasitic capacitances occur in the anti-pinch sensor between the inner first measuring electrode 4 and the outer measuring electrodes 6 and 7, so that basically a mutual shielding electrode (in FIGS. 1 to 4, shielding electrodes 30, 31, 32 and 36) can be used.

The equalizing of the bridge branches has the further result that the sum of the capacitances C1 and C2 and the capacitances C3 and C4 is identical in same series resistances (ohmic resistances R1 and R2). In this case, the voltages at the central taps are the same in phase and amplitude and therefore identical. If the contribution of the capacitive reactance of the bridge branches is selected as the same as the series resistance of the bridge branches, the measuring bridge circuit is set as most sensitive, because the phase shift in the respective bridge branches is 45°. The phase shift between the bridge branches is 0°.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An anti-pinch sensor for detecting an obstacle in the path of an actuating element of a motor vehicle, the anti-pinch sensor having a sensor body, the sensor body comprising:
a first measuring electrode arranged within the sensor body that is configured to generate a first external electric field relative to a counter electrode; and
a second measuring electrode that is electrically separated from the first measuring electrode and that is arranged within the sensor body and substantially adjacent to the first measuring electrode that is configured to generate a second external electric field relative to the counter electrode,
wherein the first or second measuring electrodes are formed such that the first external electric field has a broader range than the second external electric field.

2. The anti-pinch sensor according to claim 1, wherein the first measuring electrode is located at a distance from an edge in the sensor body and the second measuring electrode is arranged in an edge region.

3. The anti-pinch sensor according to claim 1, wherein the first and second measuring electrodes are each formed flat.

4. The anti-pinch sensor according to claim 1, wherein an area of the first measuring electrode is greater than an area of the second measuring electrode.

5. The anti-pinch sensor according to claim 1, wherein the first or second measuring electrodes are dimensioned so that a dielectric brought into the immediate vicinity in both external electric fields essentially causes no drift in the measurement capacitances relative to one another.

6. The anti-pinch sensor according to claim 1, further comprising a separate third measuring electrode that is substantially adjacent to the first measuring electrode and connected in parallel to the second measuring electrode, wherein the third measuring electrode is arranged in an edge region of the sensor body.

7. The anti-pinch sensor according to claim 6, wherein the second and third measuring electrodes are substantially identical, and wherein the first measuring electrode is arranged in the sensor body between the second and third measuring electrodes.

8. The anti-pinch sensor according to claim 1, further comprising a separate shielding electrode that is arranged relative to the first, second and third measuring electrodes to align at least the first electric field in a hazard region, the shielding electrode being provided in the sensor body.

9. The anti-pinch sensor according to claim 8, wherein the shielding electrode is divided into individual, separated single shielding electrodes, each being arranged opposite the measuring electrodes.

10. The anti-pinch sensor according to claim 1, wherein the sensor body is made of a flexible support material.

11. The anti-pinch sensor according to claim 9, wherein the sensor body is formed as a flexible flat cable.

12. The anti-pinch sensor according to claim 10, wherein a flexible conductor structure is used as the sensor body.

13. The anti-pinch sensor according to claim 1, wherein the sensor body extends substantially in a longitudinal direction, and wherein the measuring electrodes are divided along the longitudinal direction, each being divided into individually controllable single electrodes.

14. The anti-pinch sensor according to claim 13, wherein feed lines to the single electrodes in the sensor body are each arranged between shielding electrode sections.

15. An evaluation circuit for an anti-pinch sensor comprising:
a measuring potential output component configured to output a predefined measuring potential to at least a first or second measuring electrode;
a capacitance drift detection component configured to detect a mutual drift of measurement capacitances between the first or second measuring electrode and a counter electrode; and
an evaluation component configured to output a detection signal as a function of the drift signal,
wherein the anti-pinch sensor includes a sensor body comprising:
the first measuring electrode, which is arranged within the sensor body, the first measuring electrode being configured to generate a first external electric field relative to a counter electrode; and
the second measuring electrode, which is electrically separated from the first measuring electrode and is arranged within the sensor body and substantially adjacent to the first measuring electrode, the second measuring electrode being configured to generate a second external electric field relative to the counter electrode,
wherein the first or second measuring electrodes are formed such that the first external electric field has a broader range than the second external electric field.

16. The evaluation circuit according to claim 15, wherein the evaluation component is configured to output a detection signal when there is a change in the drift signal within an area corresponding to a closing time of the actuating element.

17. The evaluation circuit according to claim 15, further comprising a potential equalizing component that is configured for potential equalization between a shielding electrode and at least one of the first or second measuring electrode.

18. The evaluation circuit according to claim 17, wherein the potential equalizing component comprise an amplifier, which is connectable on an input side to one of the first or second measuring electrodes and is connectable on an output side to a shielding electrode, and wherein the potential equalizing component is configured to supply the amplifier or the first or second measuring electrodes with a voltage signal derived from an input signal.

19. The evaluation circuit according to claim 15, wherein the measuring potential output component comprise an alternative voltage source, wherein additional differential signal generation components are provided and are configured to form a differential signal corresponding to a difference between the measurement capacitances, and wherein the drift signal detection component is configured to detect the drift of the differential signal.

20. The evaluation circuit according to claim 19, wherein the differential signal generation components each comprise a bridge circuit, and wherein the measurement capacitances in the bridge branches are connected in parallel.

21. The evaluation circuit according to claim 20, wherein either a differential amplifier or a phase difference detection component are provided and configured to form the differential signal.

22. The evaluation circuit according to claim 15, wherein the measuring potential output component for the measurement capacitances in each case comprise an alternating voltage generator, wherein additional phase difference detection components are provided and configured to detect a phase difference between the measurement capacitance branches, and wherein the drift signal detection component is configured to detect the drift of the phase position.

23. The evaluation circuit according to claim 15, wherein the measurement capacitances are assigned at least one controllable balancing capacitance, and wherein the evaluation component is configured to equalize the measurement capacitances by controlling the at least one balancing capacitance.

24. The evaluation circuit according to claim 23, wherein the controllable balancing capacitances are voltage-controlled capacitance diodes that are operated in a blocking direction and are each separated from the measurement capacitances by a coupling capacitor.

25. The evaluation circuit according to claim 23, wherein the evaluation component is configured to control the balancing capacitances as a function of the drift signal.

26. A module comprising an anti-pinch sensor and an evaluation circuit connected to the anti-pinch sensor, the anti-pinch sensor comprising:
a measuring potential output component configured to output a predefined measuring potential to at least a first or second measuring electrode;
a capacitance drift detection component configured to detect a mutual drift of measurement capacitances between the first or second measuring electrode and a counter electrode; and
an evaluation component configured to output a detection signal as a function of the drift signal,
wherein the first measuring electrode, which is arranged within a sensor body, is configured to generate a first external electric field relative to a counter electrode; and
wherein the second measuring electrode, which is electrically separated from the first measuring electrode, is arranged within the sensor body and substantially adjacent to the first measuring electrode, the second measuring electrode being configured to generate a second external electric field relative to the counter electrode, and
wherein the first or second measuring electrodes are formed such that the first external electric field has a broader range than the second external electric field.

27. The anti-pinch sensor according to claim 1, wherein the counter electrode is formed by a grounded body of the motor vehicle.
